(19) United States
(12) Patent Application Publication
(10) Pub. No.: US 2022/0246733 A1
(43) Pub. Date: Aug. 4, 2022

(54) SEMICONDUCTOR DEVICE

(71) Applicant: FLOSFIA INC., Kyoto (JP)

(72) Inventors: Mitsuru OKIGAWA, Kyoto (JP); Yasushi HIGUCHI, Kyoto (JP); Yusuke MATSUBARA, Kyoto (JP)

(21) Appl. No.: 17/613,393

(22) PCT Filed: May 22, 2020
(86) PCT No.: PCT/JP2020/020429

§ 371 Date: Nov. 22, 2021

(30) Foreign Application Priority Data
May 23, 2019 (JP) 2019-097159

(51) Int. Cl. H01L 29/40; H01L 29/24; H01L 29/872

(52) U.S. Cl. CPC H01L 29/408; H02M 3/158; H01L 29/872; H01L 29/24

(57) ABSTRACT

An object of the disclosure is to provide a semiconductor device with low-loss and suppressed leakage current, which is particularly useful for power devices. A semiconductor device including a semiconductor layer, a dielectric film provided on the semiconductor layer and having an opening and provided over a distance of at least 0.25 μm from the opening, and an electrode layer provided over a part or all of the dielectric film from the inside of the opening, wherein the dielectric film has a thickness of less than 50 nm from the opening to a distance of 0.25 μm, and has relative permittivity of 5 or less.

### TECHNICAL FIELD

The disclosure relates to a semiconductor device applicable to power devices and the like.

### BACKGROUND

Gallium oxide (Ga₂O₃) is a transparent semiconductor which has a wide band gap of 4.8-5.3 eV at room temperature and hardly absorbs visible and ultraviolet light. Therefore, it is particularly a promising material for use in optical devices, electronic devices and transparent electronics operating in the deep ultraviolet light region. In recent years, as disclosed in Non-Patent Document 1, photodetectors, light-emitting diodes (LEDs), and transistors using gallium oxide have been developed.

There are five crystalline structures of gallium oxide (Ga₂O₃), α-type, β-type, γ-type, σ-type, and ε-type are known to exist, and β-Ga₂O₃ is generally the most stable structure.

However, since β-Ga₂O₃ has a β-gallia structure, unlike the crystal systems generally used in electronic materials or the like, application in a semiconductor device is not always suitable. The growth of β-Ga₂O₃ thin films requires high substrate temperature and high vacuum degree, which also increases manufacturing costs. As disclosed in Non-Patent Document 2, β-Ga₂O₃ cannot be used as a donor only by using silicon (Si) dopants having a high concentration (e.g., 1×10¹⁹/cm³ or more), and cannot be used as a donor unless annealing treatment is performed at a high temperature of 800° C. to 1100° C. after ion implantation. On the other hand, since α-Ga₂O₃ has the same crystal structure as the sapphire substrate which has been widely provided, it is suitable for use in optical devices and electronic devices. Furthermore, α-Ga₂O₃ is particularly useful for power devices due to its bandgap that is wider than that of β-Ga₂O₃. Therefore, a semiconductor device using α-Ga₂O₃ as a semiconductor is desired.

Patent Documents 1 and 2 disclose a semiconductor device using β-Ga₂O₃ as a semiconductor, also using an electrode for obtaining ohmic properties conforming to β-Ga₂O₃ semiconductor, the electrode of two layers consisting of Ti and Au layers, the electrode of the three layers consisting of Ti, Al and Au layers, or the four layers consisting of Ti, Al, Ni and Au layers. Patent Document 3 discloses a semiconductor device using β-Ga₂O₃ as a semiconductor, also using an electrode for obtaining Schottky properties conforming to β-Ga₂O₃ semiconductor, the electrode consisting of either Au layer, Pt layer, or a multilayer of Ni and Au layers. However, in the case where the electrode disclosed in Patent Documents 1 to 3 is applied to a semiconductor device using α-Ga₂O₃ as a semiconductor, the electrode does not function as a Schottky electrode or an ohmic electrode, or the semiconductor properties are degraded by the electrode to be peeled off from the semiconductor film. Furthermore, in the configuration of the electrode disclosed in Patent Documents 1 to 3, a leakage current is generated from the vicinity of an edge portion of the electrode for example, so that a semiconductor device that is practically satisfactory could not be obtained.

Patent Document 4 discloses a semiconductor device using α-Ga₂O₃ as a semiconductor and having an electrode containing at least a metal selected from Groups 4 to 9 of the Periodic Table as a Schottky electrode. Note that Patent Document 4 is a patent application filed by the present applicant.

### PRIOR TECHNICAL REFERENCE

### Patent Literature

Patent Document 1: Japanese Patent Application Publication No. 2005-260101
Patent Document 2: Japanese Patent Application Publication No. 2009-081468
Patent Document 3: Japanese Patent Application Publication No. 2013-012760
Patent Document 4: Japanese Patent Application Publication No. 2018-060992

### Non-Patent Literature

Non-Patent Document 1: Jun Liang Zhao et al, “UV and Visible Electroluminescence From a Sn:Ga₂O₃/n⁺-Si Heterojunction by Metal-Organic Chemical Vapor Deposition”, IEEE TRANSACTIONS ON ELECTRON DEVICES, VOL. 58, NO. 5 May 2011
Non-Patent Document 2: Kohei Sasaki et al, “Si-Ion Implantation Doping in β-Ga₂O₃ an d Its Application to Fabrication of Low-Resistance Ohmic Contacts”, Applied Physics Express 6 (2013) 086502

### SUMMARY

### Technical Problem

An object of the disclosure is to provide a semiconductor device with low-loss and suppressed leakage current.

### Solution to Problem

As a result of intensive studies to achieve the above object, the inventors provide a semiconductor device including a semiconductor layer, a dielectric film provided on the semiconductor layer and having an opening and provided over a distance of at least 0.25 μm from the opening, and an electrode layer provided over a part or all of the dielectric film from the inside of the opening, wherein the dielectric film has a thickness of less than 50 nm from the opening to a distance of 0.25 μm, and has relative permittivity of 5 or less. Such semiconductor device was found to extend the depletion layer in the semiconductor layer favorably, and was with low-loss and suppressed leakage current. The semiconductor device thus obtained can solve the above-mentioned problems. After the above findings, the inventors have made further research and reach the disclosure.

Embodiments of the disclosure are as follows.

[1] A semiconductor device including a semiconductor layer, a dielectric film provided on the semiconductor layer and having an opening and provided over a distance of at least 0.25 μm from the opening, and an electrode layer provided over a part or all of the dielectric film from the inside of the opening, wherein the dielectric film has a thickness of less than 50 nm from the opening to a distance of 0.25 μm, and has relative permittivity of 5 or less.

[2] The semiconductor device according to [1], wherein the dielectric film is provided over a distance of at least 0.5 μm from the opening, and the thickness of the dielectric film is less than 50 nm from the opening to a distance of 0.5 μm.

[3] The semiconductor device according to [1], wherein the dielectric film is provided over a distance of at least 1 μm from the opening, and the thickness of the dielectric film is less than 50 nm from the opening to a distance of 1 μm.

[4] The semiconductor device according to [1], wherein the semiconductor layer contains an oxide semiconductor as a main component.

[5] The semiconductor device according to [4], wherein the oxide semiconductor contains at least one or more metals selected from aluminum, indium and gallium.

[6] The semiconductor device according to [4], wherein the oxide semiconductor contains at least gallium.

[7] The semiconductor device according to [4], wherein the oxide semiconductor has corundum structure.

[8] The semiconductor device according to [1], wherein the electrode layer contains at least one metal selected from Groups 4 to 10 of the Periodic Table.

[9] The semiconductor device according to [1], wherein the electrode layer contains at least one metal selected from Groups 4 and 9 of the Periodic Table.

[10] The semiconductor device according to [1], wherein the electrode layer includes two or more layers having different compositions.

[11] The semiconductor device according to [1], wherein a thickness of the dielectric film at a position of an outer edge portion of the electrode layer is thicker than a thickness of the dielectric film from the opening to a distance of 1 μm.

[12] The semiconductor device according to [1], wherein the density of fixed charges in the semiconducting layers is 1×10¹⁷/cm³ or less.

[13] The semiconductor device according to any one of [1] to [12], wherein the semiconductor device includes a Schottky barrier diode.

[14] The semiconductor device according to any one of [1] to [13], wherein the semiconductor device includes a power device.

[15] A semiconductor system employing the semiconductor device according to any one of [1] to [14].

### Advantageous Effect of Invention

According to the disclosure, a semiconductor device with low-loss and suppressed leakage current is provided.

### BRIEF DESCRIPTION OF DRAWINGS

FIG. 1 is a cross-sectional view schematically illustrating a Schottky barrier diode (SBD) according to one or more preferred embodiments of a semiconductor device of the disclosure.

FIG. 2 is a cross-sectional view schematically illustrating a Schottky barrier diode (SBD) according to one or more preferred embodiments of a semiconductor device of the disclosure.

FIG. 3 is a cross-sectional view schematically illustrating a Schottky barrier diode (SBD) according to one or more preferred embodiments of a semiconductor device of the disclosure.

FIG. 4 is a block diagram illustrating a mist CVD apparatus used for a semiconductor device according to one or more embodiments of the disclosure.

FIG. 5 is a diagram schematically illustrating a power supply system employing a semiconductor device according to one or more preferred embodiments of the disclosure.

FIG. 6 is a diagram schematically illustrating a system device employing a semiconductor device according to one or more preferred embodiments of the disclosure.

FIG. 7 is a circuit diagram illustrating a power supply of a power supply device employing a semiconductor device according to one or more preferred embodiments of the disclosure.

FIG. 8 is a graph illustrating simulation results in the embodiment, in which a vertical axis represents reverse current and a horizontal axis represents thickness of a dielectric film.

FIGS. 9A to 9D are simulation diagrams illustrating evaluation results of electric field distributions around a dielectric film generated when a current is applied to a semiconductor device of a preferred embodiment of the disclosure. FIG. 9A is a simulation diagram when thickness of the dielectric film from an aperture portion to a distance of 0.25 μm is less than 50 nm. FIG. 9B is a simulation diagram when thickness of the dielectric film from an aperture portion to a distance of 0.5 μm is less than 50 nm. FIG. 9C is a simulation diagram when thickness of the dielectric film from an aperture portion to a distance of 0.75 μm is less than 50 nm. FIG. 9D is a simulation diagram when thickness of the dielectric film from an aperture portion to a distance of 1 μm is less than 50 nm.

FIG. 10 is a graph illustrating the results of simulations shown in FIGS. 9A to 9D as examples and a comparative example, in which a vertical axis represents current and a horizontal axis represents voltage.

FIGS. 11A and 11B are diagrams illustrating simulation data of evaluation results of the electric field distribution around a dielectric film generated when a current is applied to a semiconductor device in one or more embodiments of the disclosure. FIG. 11A is a diagram illustrating the simulation data when the film thickness of the dielectric film from the opening to a distance of 1 μm is less than 50 nm, and the film thickness increases to a certain distance at a rate of taper angle 45° after exceeding 1 μm. FIG. 11B is a diagram illustrating the simulation data when the film thickness of the dielectric film from the opening to a distance of 1 μm is less than 50 nm, and the film thickness increases to a certain distance at a rate of taper angle 20° after exceeding 1 μm.

FIG. 12 is a cross-sectional view schematically illustrating a Schottky barrier diode (SBD) according to one or more preferred embodiments of a semiconductor device of the disclosure.

FIG. 13 is a graph illustrating results of I-V measurements in Examples and Comparative Examples.

### DESCRIPTION OF EMBODIMENT

The semiconductor device of the disclosure includes a semiconductor layer, a dielectric film provided on the semiconductor layer and having an opening and provided over a distance of at least 0.25 μm from the opening, and an electrode layer provided over a part or all of the dielectric film from the inside of the opening, wherein the dielectric film has a thickness of less than 50 nm from the opening to a distance of 0.25 μm, and has relative permittivity of 5 or less. In the disclosure, it is preferable that the dielectric film is provided over a distance of at least 0.5 μm from the opening, and the thickness of the dielectric film is less than 50 nm from the opening to a distance of 0.5 μm. It is more preferable that the dielectric film is provided over a distance of at least 0.75 μm from the opening, and the thickness of the dielectric film is less than 50 nm from the opening to a distance of 0.75 μm. It is most preferable that the dielectric film is provided over a distance of at least 1 μm from the opening, and the thickness of the dielectric film is less than 50 nm from the opening to a distance of 1 μm.

The semiconductor layer preferably contains an oxide semiconductor as a main component, more preferably contains at least one or more metals selected from aluminum, indium, and gallium, and most preferably contains at least gallium. The semiconductor layer preferably contains an oxide semiconductor having a corundum structure as a main component. Examples of the oxide semiconductor having the corundum structure include a metal oxide containing one or more metals selected from aluminum, gallium, indium, iron, chromium, vanadium, titanium, rhodium, nickel, cobalt, and iridium. In the disclosure, the oxide semiconductor preferably contains at least one metal selected from aluminum, indium, and gallium, and more preferably, the oxide semiconductor contains at least gallium, and most preferably, the oxide semiconductor contains α-Ga₂O₃ or a mixed crystal thereof. Note that “main component” is meant that the atomic ratio of the oxide semiconductor having the corundum structure relative to all components of the semiconductor layer is preferably 50% or more, more preferably 70% or more, and even more preferably 90% or more, and may be 100%. Thickness of the semiconductor layer is not particularly limited, and may be 1 μm or less, or may be 1 μm or more. In the disclosure, it is preferably 1 μm or more, and more preferably 10 μm or more. Surface area of the semiconductor film is not particularly limited, and may be 1 mm² or more, or 1 mm² or less. In the disclosure, the surface area of the semiconductor film is preferably 10 mm²˜300 cm², and more preferably 100 mm²˜100 cm². The semiconductor layer is typically a single crystal, but may be polycrystalline. The semiconductor layer is a multilayer film including at least a first semiconductor layer and a second semiconductor layer. When the Schottky electrode is provided on the first semiconductor layer, the multilayer film is also preferable that the carrier density of the first semiconductor layer is smaller than the carrier density of the second semiconductor layer. In this case, the second semiconductor layer typically contains a dopant, and the carrier density of the semiconductor layer can be appropriately set by adjusting the doping amount.

The semiconductor layer preferably contains a dopant. The dopant is not particularly limited and may be a known dopant. Examples of the dopant include n-type dopants such as tin, germanium, silicon, titanium, zirconium, vanadium or niobium, or p-type dopants such as magnesium, calcium, and zinc. In the disclosure, it is preferred that the n-type dopant is tin, germanium or silicon. Content of the dopant in the composition of the semiconductor layer is preferable 0.00001 atomic % or more, more preferably 0.00001 atomic % to 20 atomic %, and most preferably 0.00001 atomic % to 10 atomic %. More specifically, the concentration of the dopant in the semiconductor layer may typically be about 1×10¹⁶/cm³ to 1×10²²/cm³, or the concentration of the dopant in the semiconductor layer may be as low as, for example, about 1×10¹⁷/cm³ or less. Further, in the disclosure, the semiconductor layer may contain dopants at high concentrations of about 1×10²⁰/cm³ or more. Concentration of the fixed charges in the semiconductor layer is not particularly limited, and in the disclosure, it is preferable 1×10¹⁷/cm³ or less because a depletion layer can be favorably formed in the semiconductor layer.

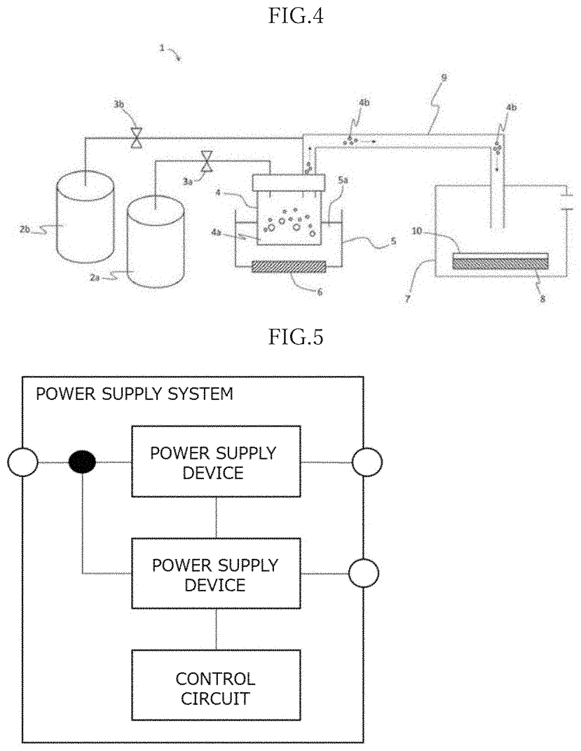

The semiconductor layer may be formed by using a known method. Examples of a method for forming the semiconductor layer includes a CVD method, a MOCVD method, a MOVPE method, a mist-CVD method, a mist-epitaxy method, a MBE method, a HVPE method, a pulsed growth method, an ALD method, and the like. In the disclosure, the method of forming the semiconductor layer is preferably a mist CVD method or a mist epitaxy method. In the mist CVD method or the mist epitaxy method, for example, a mist CVD apparatus shown in FIG. 4 is used to atomize a raw material solution to float droplets (atomizing step), and thereafter, atomized droplets are conveyed to the vicinity of a substrate by a carrier gas (conveying step), and then the atomized droplets are thermally reacted in the vicinity of the substrate, whereby a semiconductor film containing a crystalline oxide semiconductor as a main component is deposited on the substrate and the semiconductor layer is formed (deposition step) on the substrate.

### (Atomizing Step)

In the atomizing step, the raw material solution is atomized. The method of atomizing the raw material solution is not particularly limited as long as the raw material solution can be atomized, and may be a known method. In the disclosure, ultrasonic waves are preferably used as an atomizing method. Droplets atomized using ultrasonic waves are preferred because they have an initial velocity of zero and are floated in the air. The droplets can be conveyed as a gas by floating in a space instead of being sprayed like a spray. It is very preferable because of no damage by collision energy. The size of the droplet is not particularly limited, and may be about several millimeters, preferably 50 μm or less, and more preferably 100 nm to 10 μm.

### (Raw Material Solution)

The raw material solution is not particularly limited as long as it is capable of atomization or droplet formation and contains a raw material capable of forming the semiconductor film. The raw material may be an inorganic material or an organic material. In the disclosure, the raw material is preferably a metal or a metal compound, and more preferably includes one or more kinds of metals selected from aluminum, gallium, indium, iron, chromium, vanadium, titanium, rhodium, nickel, cobalt and iridium.

In the disclosure, it is preferable to use a material in which the metal is dissolved or dispersed in an organic solvent or water in the form of complex or salt as the raw material solution. Examples of the form of the complex include acetylacetonate complex, carbonyl complex, ammine complex, and hydride complex. Examples of the form of the salt include an organometallic salt (metal acetate, metal oxalate, metal citrate, and the like), metal sulfide salt, nitrified metal salt, phosphorylated metal salt, and halogenated metal salt (metal chloride, metal bromide, metal iodide, and the like).

In the raw material solution, it is preferable to mix an additive such as hydrohalic acid or oxidizing agent. Examples of the hydrohalic acid include hydrobromic acid, hydrochloric acid, and hydroiodic acid. For the reason that the occurrence of abnormal grains can be more efficiently suppressed, hydrobromic acid or hydroiodic acid is more preferable. Examples of the oxidizing agent include peroxide such as hydrogen peroxide (H₂O₂), sodium peroxide (Na₂O₂), barium peroxide (BaO₂), benzoyl peroxide (peroxide such as C₆H₅CO)₂O₂), and organic peroxides such as hypochlorous acid (HClO), perchloric acid, nitric acid, ozone water, peracetic acid and nitrobenzene.

A dopant may be contained in the raw material solution. By including a dopant in the raw material solution, doping can be favorably performed. Material of the dopant is not particularly limited as long as it does not deviate the object of the disclosure. Examples of the dopant include an n-type dopant such as tin, germanium, silicon, titanium, zirconium, vanadium, or niobium, or a p-type dopant such as Mg, H, Li, Na, K, Rb, Cs, Fr, Be, Ca, Sr, Ba, Ra, Mn, Fe, Co, Ni, Pd, Cu, Ag, Au, Zn, Cd, Hg, Ti, Pb, N, or P. The content of the dopant is appropriately set by referring to a calibration curve showing the relationship of the concentration of the dopant in the raw material with respect to the desired carrier density.

The solvent of the raw material solution is not particularly limited, and may be inorganic solvent such as water, organic solvent such as alcohol, or mixed solvent of inorganic solvent and organic solvent. In the disclosure, it is preferable that the solvent contains water, and more preferably, the solvent is water or a mixed solvent of water and alcohol.

### (Conveying Step)

In the conveying step, the atomized droplets are conveyed into a deposition chamber using a carrier gas. The carrier gas is not particularly limited as long as it does not deviate the object of the disclosure, and examples thereof include an inert gas such as oxygen, ozone, nitrogen or argon, or a reducing gas such as hydrogen gas or a forming gas. The type of the carrier gas may be one, and two or more types may be accepted. Dilution gas (such as 10-fold diluent gas) having reduced flow rate may be further applied as the second carrier gas.

The carrier gas may be supplied not only at one point but also at two or more points in the deposition chamber. Flow rate of the carrier gas is not particularly limited, and is preferably 0.01 to 20 L/min, more preferably 1 to 10 L/min. When dilution gas is used, the flow rate of the dilution gas is preferably 0.001 to 2 L/min, more preferably 0.1 to 1 L/min.

### (Deposition Step)

In the deposition step, the semiconductor film is deposited on the base by thermally reacting the atomized droplets in the vicinity of the base. The thermal reaction may be performed so long as the atomized droplets react with heat, and the reaction conditions and the like are not particularly limited as long as they do not deviate the object of the disclosure. In this deposition step, the thermal reaction is generally performed at a temperature equal to or higher than an evaporation temperature of the solvent, and in that case, temperature (e.g., 1000° C. or less) which is not too high is preferable, and more preferably 650° C. or less, and most preferably 300° C. to 650° C. The thermal reaction may be performed under a vacuum, under a non-oxygen atmosphere (under an inert gas atmosphere or the like), under a reducing gas atmosphere and under an oxygen atmosphere as long as it does not deviate the object of the disclosure, and is preferably performed under an inert gas atmosphere or an oxygen atmosphere. The deposition step may be performed under any condition under atmospheric pressure, under pressure and under reduced pressure, and is preferably performed under atmospheric pressure in the disclosure. The film thickness can be set by adjusting the deposition time.

### (Base)

A base is not particularly limited as long as the base can support the semiconductor film. Material of the base is not particularly limited as long as it does not deviate the object of the disclosure, and may be a known base. The base may be an organic compound or an inorganic compound. The base may be of any shape, for example, a plate such as a flat plate or a disc plate, fibrous, rodlike, column, prismatic, cylindrical, spiral, spherical, and ring-shaped. In the disclosure, the base is preferably a substrate. Thickness of the substrate is not particularly limited in the disclosure.

The substrate is not particularly limited as long as the substrate is in the shape of plate and can support the semiconductor film. The substrate may be an insulator substrate, a semiconductor substrate, a metal substrate, or a conductive substrate. The substrate is preferably the insulator substrate, and is also preferable to have a metal film on its surface. Examples of the substrate include a base substrate containing a substrate material having corundum structure as a main component, a base substrate containing a substrate material having β-gallia structure as a main component, and a base substrate containing a substrate material having hexagonal crystal structure as a main component. The term “main component” means that the atomic ratio of the substrate material having the specific crystal structure to all components of the material constituting the substrate is preferably 50% or more, more preferably 70% or more, and still more preferably 90% or more, and may be 100%.

Material of the substrate is not particularly limited as long as it does not deviate the object of the disclosure, and may be a known one. As the substrate having the corundum structure, it is preferable to employ a α-Al₂O₃ (sapphire) substrate or a α-Ga₂O₃ substrate, more preferably an a-plane sapphire substrate, an m-plane sapphire substrate, an r-plane sapphire substrate, a c-plane sapphire substrate, or a α-type gallium oxide substrate (a-plane, m-plane, or r-plane). As the base substrate containing the β-gallia-structured substrate material as a main component, a β-Ga₂O₃ substrate, or a mixed crystal substrate containing Ga₂O₃ and Al₂O₃ in which Al₂O₃ is more than 0 wt % and 60 wt % or less may be selected for example. Examples of the base substrate containing the hexagonal-structured substrate material as a main component include a SiC substrate, a ZnO substrate, and a GaN substrate.

In the disclosure, annealing treatment may be performed after the deposition step. Temperature for the aforementioned annealing treatment is not limited as long as it does not deviate the object of the disclosure, and is generally 300° C. to 650° C., and is preferably 350° C. to 550° C. Processing time of the annealing treatment is generally in 1 minute to 48 hours, preferably in 10 minutes to 24 hours, and more preferably in 30 minutes to 12 hours. The annealing treatment may be performed under any atmosphere so long as it does not deviate the object of the disclosure. The atmosphere of the annealing treatment may be a non-oxygen atmosphere or an oxygen atmosphere. Examples of the non-oxygen atmosphere include an inert gas atmosphere (such as a nitrogen atmosphere) or a reducing gas atmosphere. In the disclosure, the non-oxygen atmosphere is preferably the inert gas atmosphere, more preferably the nitrogen atmosphere.

In the disclosure, the semiconductor film may be deposited directly on the base, or the semiconductor film may be deposited via another layer such as a stress relaxation layer (a buffer layer, an ELO layer, or the like), a release sacrifice layer, or the like. Method of forming each of the layers is not particularly limited, and may be a known method. In the disclosure, a method of forming each of the layers is preferably a mist CVD method.

In the disclosure, the semiconductor film may be applied to the semiconductor device as the semiconductor layer after being peeled off from the base or the like by a known method, or without being peeled off from the base or the like.

The electrode layer is not particularly limited as long as it has conductivity and can be used as an electrode and does not deviate the object of the disclosure. Constituent material of the electrode layer may be a conductive inorganic material or a conductive organic material. In the disclosure, the material of the electrode layer is preferably a metal. Preferable example of the metal includes at least one metal selected from Groups 4 to 10 of the Periodic Table. Examples of the metal of Group 4 of the Periodic Table include titanium (Ti), zirconium (Zr), and hafnium (Hf). Examples of the metal of Group 5 of the Periodic Table include vanadium (V), niobium (Nb), and tantalum (Ta). Examples of the metal of Group 6 of the Periodic Table include chromium (Cr), molybdenum (Mo), and tungsten (W). Examples of the metal of Group 7 of the Periodic Table include manganese (Mn), technetium (Tc), and rhenium (Re). Examples of the metal of Group 8 of the Periodic Table include iron (Fe), ruthenium (Ru), and osmium (Os). Examples of the metal of Group 9 of the Periodic Table include cobalt (Co), rhodium (Rh), and iridium (Ir). Examples of the metal of Group 10 of the Periodic Table include nickel (Ni), palladium (Pd), and platinum (Pt). In the disclosure, it is preferable that the electrode layer contains at least one metal selected from Groups 4 and 9 of the Periodic Table, and more preferably, a metal selected from Group 9 metal of the Periodic Table. Thickness of the electrode layer is not particularly limited, and is preferably 0.1 nm to 10 μm, more preferably 5 nm to 500 nm, and most preferably 10 nm to 200 nm. In the disclosure, it is preferable that the electrode layer is made of two or more layers having different compositions from each other.

By such a preferred configuration of the electrode layer, it is possible to obtain a semiconductor device with enhanced Schottky properties, and to suppress the leakage current effectively.

When the electrode layer is formed of two or more layers including the first electrode layer and the second electrode layer, it is preferable that the second electrode layer has conductivity, and the conductivity is higher than that of the first electrode layer. Constituent material of the second electrode layer may be a conductive inorganic material or a conductive organic material. In the disclosure, it is preferable that the material of the second electrode is a metal. Preferable examples of the metal include at least one metal selected from Groups 8 to 13 of the Periodic Table. The metals of Groups 8 to 10 of the Periodic Table include the metals exemplified as the metals of Groups 8 to 10 of the Periodic Table in the description of the electrode layer. Examples of the metal of Group 11 of the Periodic Table include copper (Cu), silver (Ag), and gold (Au). Examples of the metal of Group 12 of the Periodic Table include zinc (Zn) and cadmium (Cd). Examples of the metal of Group 13 of the periodic table include aluminum (Al), gallium (Ga), and indium (In). In the disclosure, it is preferable that the second electrode layer contains at least one metal selected from Groups 11 and 13 of the Periodic Table, and more preferably contains at least one metal selected from silver, copper, gold and aluminum. Note that thickness of the second electrode layer is not particularly limited, but is preferably 1 nm to 500 μm, more preferably 10 nm to 100 μm, and most preferably 0.5 μm to 10 μm. In the disclosure, the thickness of the dielectric film at the position of the outer edge portion of the electrode layer is thicker than the thickness of the dielectric film from the opening to a distance of 1 μm. It makes possible to obtain a semiconductor device with further improved breakdown voltage.

Method of forming the electrode layer is not particularly limited, and may be a known method. Specific examples of the method for forming the electrode layer include a dry method, a wet method, and the like. Examples of the dry method include a sputtering, a vacuum evaporation, and a CVD. Examples of the wet method include a screen printing and a die coating.

It is preferable that the outer edge portion of the first electrode layer is located outside the outer edge portion of the second electrode layer. In the disclosure, by setting the distance between the outer edge portion of the first electrode layer and the outer edge portion of the second electrode layer to 1 μm or more, leakage current can be effectively suppressed. In the disclosure, a portion of the first electrode layer protruding outward from the outer edge of the second electrode layer (hereinafter, referred to as “protruding part”) may, at least partially, have a tapered region in which thickness of the first electrode layer decreases toward the outer side of the semiconductor device. It makes possible to further improve breakdown voltage of the semiconductor device. By combining such an electrode configuration and the constituent material of the semiconductor layer described above, a semiconductor device having a lower loss with the leakage current being favorably suppressed is provided.

The dielectric film is formed on the semiconductor layer and has an opening, and is formed over a distance of at least 1 μm from the opening. The dielectric film is not particularly limited as long as it has relative permittivity of 5 or less and does not deviate the object of the disclosure, and may be a known dielectric film. The term “relative permittivity” is expressed by the ratio of permittivity of the film and the permittivity in vacuum. In the disclosure, it is preferable that the dielectric film is a film containing Si. Preferred examples of the film containing Si include a silicon oxide-based film. Examples of the silicon oxide-based film include a SiO₂ film, a SiO₂ film with phosphorus added (PSG), a SiO₂ film with boron added, a SiO₂ film with phosphorus and boron added (BPSG), SiOC film, and a SiOF film. A method of forming the dielectric film is not particularly limited. Examples of the method of forming the dielectric film includes a CVD method, an atmospheric pressure CVD method, a plasma CVD method, a mist CVD method, and a thermal oxidation method. In the disclosure, the method of forming the dielectric film is preferably a mist CVD method or an atmospheric pressure CVD method.

Hereinafter, preferred embodiments of the semiconductor device will be described in more detail with reference to the drawings. Note that the disclosure is not limited to the following embodiments.

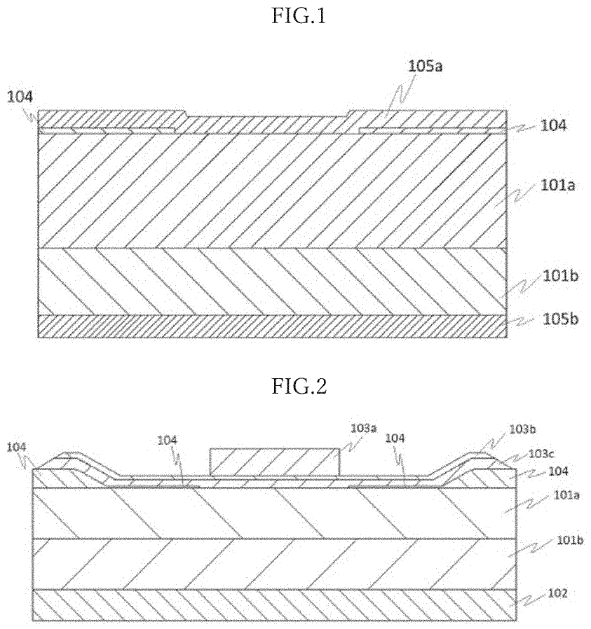

FIG. 1 is a cross-sectional view illustrating a main part of a Schottky barrier diode (SBD) as one of the preferred embodiments of the semiconductor device of the disclosure. The SBD shown in FIG. 1 includes an ohmic electrode 105b, an n⁻-type semiconductor layer 101a, an n⁺-type semiconductor layer 101b, a Schottky electrode 105a, and a dielectric film 104. The dielectric film 104 is formed on the n⁻-type semiconductor layer 101a and has an opening. The dielectric film 104 is formed over a distance of at least 1 μm from the opening, and a film thickness from the opening to a distance of 1 μm is less than 50 nm. The semiconductor device shown in FIG. 1 can suppress leakage current favorably by providing the dielectric film 104.

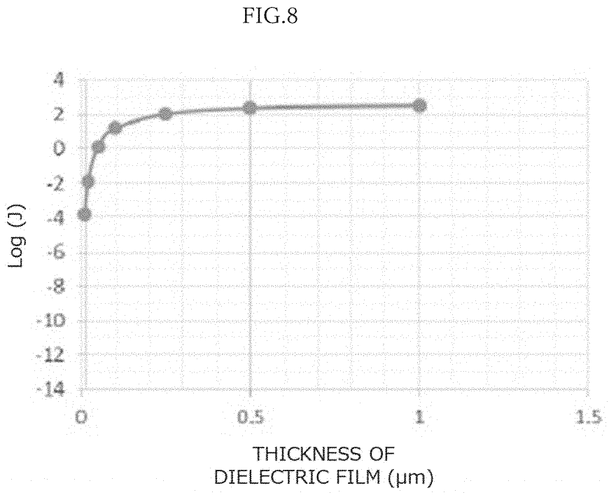

In the SBD shown in FIG. 1, when Co was used as the Schottky electrode 105a, α-Ga₂O₃ was used as the n⁻-type semiconductor layer 101a, and a SiO₂ film was used as the dielectric film 104, the dependency of the reverse current (@Vr=200V) on the thickness of the dielectric film at temperature of 300K was evaluated by simulations. The evaluation results are shown in the graph of FIG. 8. As is obvious from FIG. 8, when the thickness of the dielectric film 104 is less than 50 nm, the effect of suppressing the leakage current is remarkably observed.

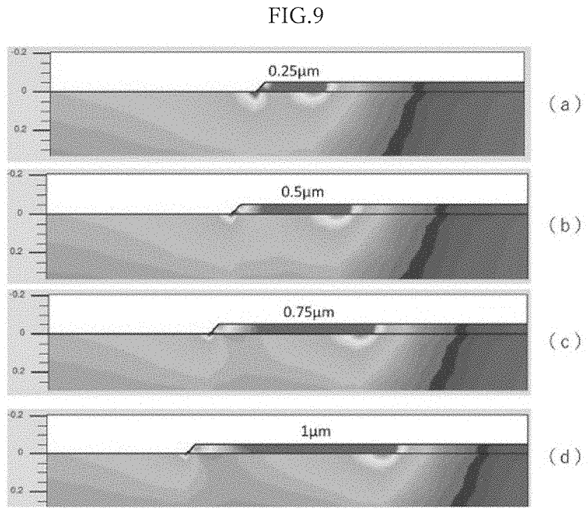

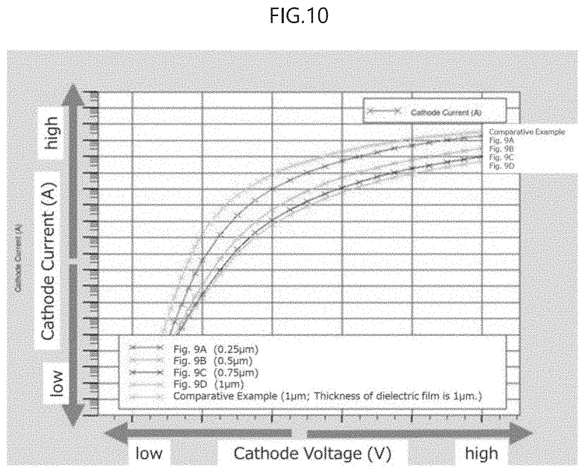

Further, in the SBD shown in FIG. 1, the electric field distribution around the dielectric film generated when a current is applied to the semiconductor device, was simulated. The evaluation results are shown in FIGS. 9A to 9D. The respective leakage currents of FIGS. 9A to 9D were also simulated and evaluated. The evaluation results are shown in FIG. 10. FIG. 9A is a simulation diagram illustrating an evaluation result in the case where the dielectric film is formed from the opening to a distance of 25 μm or more, and the thickness of the dielectric film from the opening to a distance of 0.25 μm is less than 50 nm. Referring to FIGS. 9A and 10, when the thickness of the dielectric film from the opening to a distance of 0.25 μm is less than 50 nm, in comparison with Comparative Example in which thickness of the dielectric film from the opening to a distance of 1 μm is 1 μm, it is obvious that the leakage current can be significantly reduced and the depletion layer can be satisfactorily expanded. FIG. 9B is a simulation diagram illustrating an evaluation result in the case where the dielectric film is formed from the opening to a distance of 0.5 μm or more, and the thickness of the dielectric film from the opening to a distance of 0.5 μm is less than 50 nm. Referring to FIGS. 9B and 10, when the thickness of the dielectric film from the opening to a distance of 0.5 μm is less than 50 nm, in comparison with Comparative Example in which thickness of the dielectric film from the opening to a distance of 1 μm is 1 μm, it is obvious that the leakage current can be remarkably reduced and the depletion layer can be more satisfactorily expanded. FIG. 9C is a simulation diagram illustrating an evaluation result in the case where the dielectric film is formed from the opening to a distance of 0.75 μm or more, and the thickness of the dielectric film from the opening to a distance of 0.75 μm is less than 50 nm. Referring to FIGS. 9C and 10, when the thickness of the dielectric film from the opening to a distance of 0.75 μm is less than 50 nm, in comparison with Comparative Example in which thickness of the dielectric film from the opening to a distance of 1 μm is 1 μm, it is obvious that the leakage current can be remarkably reduced and the depletion layer can be more satisfactorily expanded. FIG. 9D is a simulation diagram illustrating an evaluation result in the case where the dielectric film is formed from the opening to a distance of 1 μm or more, and the thickness of the dielectric film from the opening to a distance of 1 μm is less than 50 nm. Referring to FIGS. 9D and 10, when the thickness of the dielectric film from the opening to a distance of 1 μm is less than 50 nm, in comparison with Comparative Example in which thickness of the dielectric film from the opening to a distance of 1 μm is 1 μm, it is obvious that the leakage current can be remarkably reduced and the depletion layer can be more satisfactorily expanded.

FIG. 2 is a cross-sectional view illustrating a main part of a Schottky barrier diode (SBD) as one of other preferred embodiments of the semiconductor device of the disclosure. In the SBD shown in FIG. 2, the Schottky electrode further includes metal layers 103a, 103b, and 103c. Unlike the SBD shown in FIG. 1, the thickness of the dielectric film 104 at the outer edge portion of the Schottky electrode is formed to be thicker than the thickness of the dielectric film 104 from the opening of the dielectric film 104 to a distance of 1 μm. With such a configuration, it is possible to further improve breakdown voltage of the semiconductor device.

Method of forming each layer shown in FIG. 2 is not particularly limited as long as it does not deviate the object of the disclosure, and may be a known method. Patterning by a photolithography method after deposition using a vacuum deposition method, a CVD method, a sputtering method or various coating methods, or by a method of performing direct patterning using a printing technique or the like may be employed.

Hereinafter, the disclosure will be explained in more detail by referring preferred examples for manufacturing the semiconductor device shown in FIG. 2.

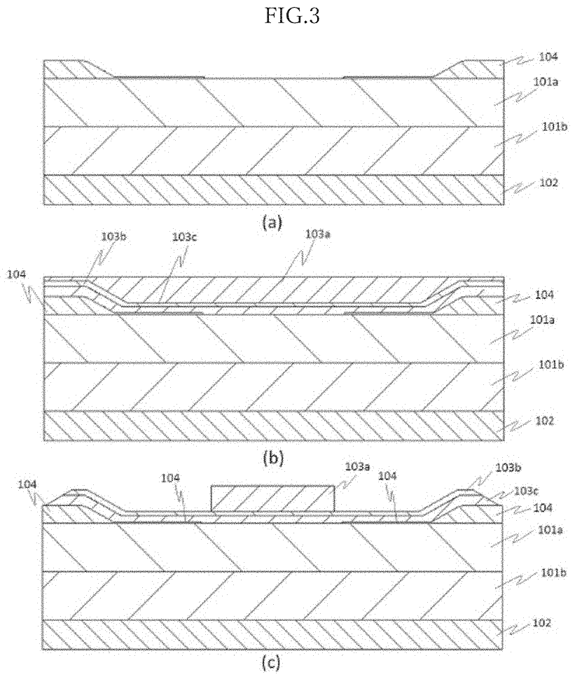

FIG. 3A shows a multilayer constituted such that the n⁺-type semiconductor layer 101b and the n⁻-type semiconductor layer 101a are formed in this order on the ohmic electrode 102, and that the dielectric film 104 is formed on the n⁻-type semiconductor layer. Method of forming the dielectric film 104 is not particularly limited as long as it does not deviate the object of the disclosure. Examples of a method for forming the dielectric film 104 include a sputtering method, a vacuum evaporation method, a coating method, a CVD method, an atmospheric pressure CVD method, a plasma CVD method, a mist CVD method, and a thermal oxidation method. In the disclosure, a mist CVD method or an atmospheric pressure CVD method is preferable. An opening for forming the first electrode layer is provided in the dielectric film 104 so that at least a part of the n⁻-type semiconductor layer 101a is exposed. Method of forming the opening is not particularly limited, and may be a known etching method. A tapered portion is formed in the dielectric film 104 such that the film thickness decreases from the outer side to the inner side of the semiconductor device. Method of forming the tapered portion is not particularly limited as long as it does not deviate the object of the disclosure, and may be a known method.

Based on the configuration of FIG. 3A, simulation was performed to evaluate the electric field distribution around the dielectric film generated when a current was applied to the semiconductor device. The evaluation results are shown in FIG. 11. FIG. 11A shows the evaluation result in the case where film thickness of the dielectric film from the opening to a distance of 1 μm is less than 50 nm, and the film thickness is increased by a certain distance at a rate of taper angle 45° after exceeding the distance of 1 μm. FIG. 11B shows the evaluation result in the case where film thickness of the dielectric film from the opening to a distance of 1 μm is less than 50 nm, and the film thickness is increased by a certain distance at a rate of taper angle 20° after exceeding the distance of 1 μm. As is apparent from FIGS. 11A and 11B, the semiconductor device having such tapered portion as described above can also reduce the leakage current suitably, and expand the depletion layer favorably.

Next, metal layers 103a, 103b, and 103c are formed on the multilayer shown in FIG. 3A using the dry method or the wet method to obtain a multilayer shown in FIG. 3B. Thereafter, excess portions of the metal layers 103a, 103b, and 103c are removed by using a known etch method to obtain a multilayer shown in FIG. 3C. In the removal by the etching, it is preferable, by the etching step is made while the resist is retreated, for example, the outer edge portion of the first electrode is formed to be a tapered shape. The semiconductor device obtained as described above, the leakage current is suppressed, and has improved breakdown voltage.

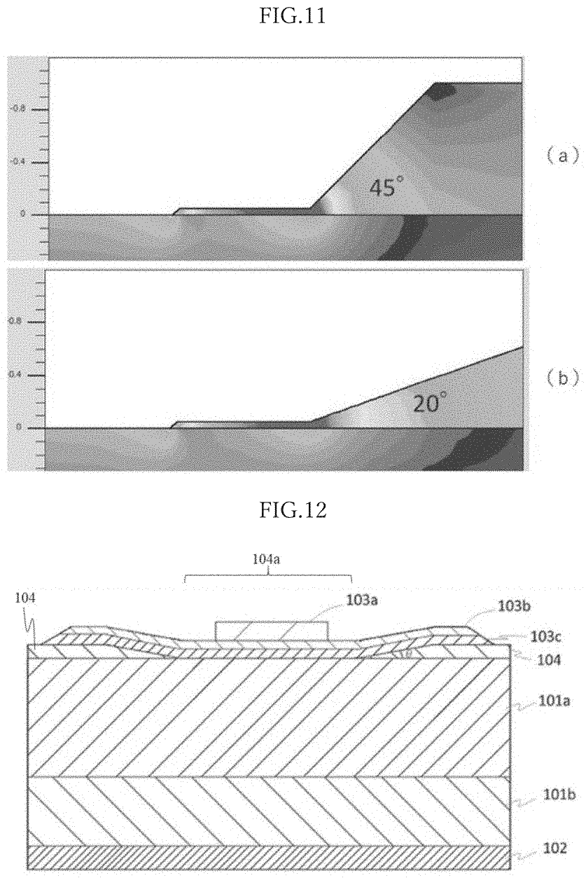

FIG. 12 is a cross-sectional view illustrating a main portion of a Schottky barrier diode (SBD) in another preferred embodiment of a semiconductor device of the disclosure. The SBD shown in FIG. 12 includes the ohmic electrode 102, the n⁻-type semiconductor layer 101a, the n⁺-type semiconductor layer 101b, the Schottky electrode 103, and the dielectric film 104. In the SBD shown in FIG. 12, the Schottky electrode has metal layers 103a, 103b, and 103c. Unlike the SBD shown in FIG. 1, the dielectric film 104 has a tapered portion such that the film thickness increases from the inner side to the outer side of the semiconductor device from the opening 104a to a distance of at least 0.25 μm.

Method of forming each layer shown in FIG. 12 is not particularly limited as long as it does not deviate the object of the disclosure, and may be a known method. Patterning by a photolithography method after deposition using a vacuum deposition method, a CVD method, a sputtering method or various coating methods, or by a method of performing direct patterning using a printing technique or the like may be employed. Method of forming the tapered portion of the dielectric film is not particularly limited as long as it does not deviate the object of the disclosure, and may be a known method.

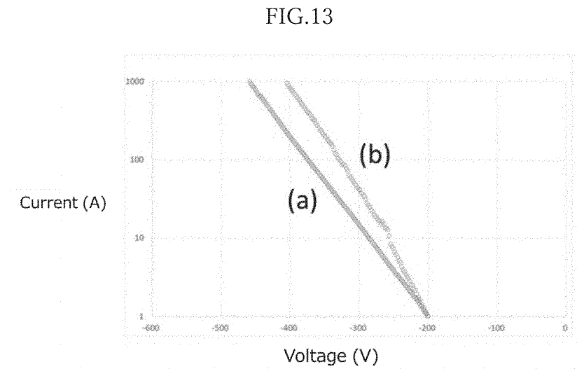

In the SBD shown in FIG. 12, the SBD was fabricated using Al, Ti and Co as the metal layers 103a, 103b, and 103c of the Schottky electrode, α-Ga₂O₃ as the n⁻-type and n⁺-type semiconductor layers 101a and 101b, SiO2 as the dielectric film 104, and a multilayer of Ti/Ni/Au as the ohmic electrode 102. I-V measurements of the SBD thus fabricated were performed. FIG. 13 is a graph illustrating results of I-V measurements in which the current value on the vertical axis is normalized by the current value at −200V of reverse direction voltage is applied. Line (a) in FIG. 13 indicates a result of I-V measurement of the SBD in which the tapered portion is formed such that the thickness of the dielectric film from the opening to a distance of 0.25 μm is less than 50 nm. Line (b) in FIG. 13 indicates a result of I-V measurement of the SBD in which the tapered portion is formed such that the thickness of the dielectric film from the opening to a distance of 1.00 μm is 1.00 μm. As is obvious from FIG. 13, when the thickness of the dielectric film 104 was less than 50 nm, leakage current was remarkably suppressed.

The semiconductor device according to one or more embodiments of the disclosure is particularly useful for power devices. As the semiconductor device, a diode (PN diode, Schottky barrier diode, junction barrier Schottky diode, etc.) or a transistor (such as a MOSFET, MESFET) and the like are given as examples. Among them, a diode is preferable, and Schottky barrier diode (SBD) is more preferable. The disclosed semiconductor device is not limited to above explained embodiments and can be suitably used as power modules, inverters or converters using known methods.

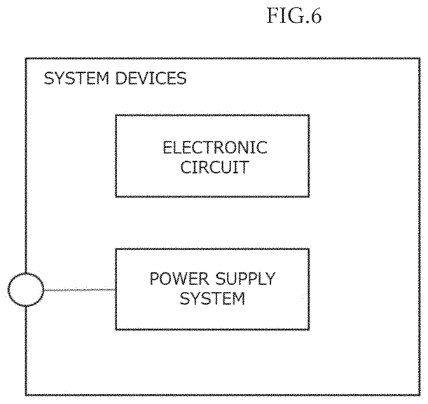

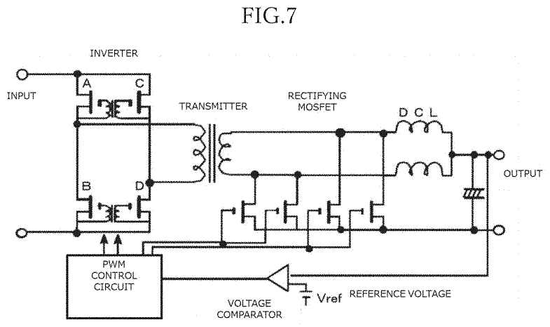

The power modules, inverters and converters are also included in the semiconductor device of the present disclosure. Further, the semiconductor device of the disclosure is suitable for use in semiconductor systems and the like using a power supply device. The power supply device can be manufactured with or as the semiconductor device by connecting the power supply device to wiring patterns by known methods. FIG. 5 shows an example of a power supply system configured by a plurality of the power supply device and a control circuit. As shown in FIG. 6, the power supply system can be used to system device by combining with electronic circuit. FIG. 7 shows a power supply of the power supply device including a power circuit and a control circuit. In the power supply, an input DC voltage is converted to AC voltage by high-frequency switching by an inverter (constituted by MOSFETs A to D), and insulated and transformed by a transformer, rectified by a rectifying MOSFETs A to B′, and then smoothed by a DCL (smoothing coils L1 and L2) and a capacitor to generate an output DC voltage. Further, the output voltage and a reference voltage are compared by a voltage comparator so that the inverters and the rectifying MOSFETs are controlled by a PWM control circuit to generate the output DC voltage to be a desired value.

### INDUSTRIAL APPLICABILITY

The semiconductor device of the disclosure can be applied to products of various technical fields such as semiconductors (compound semiconductor electronic devices, etc.), electronic components and electrical equipment components, optical and electrophotographic related devices and industrial members. Among others, it is particularly useful for power devices.

### DESCRIPTION OF SYMBOLS

1 deposition apparatus (mist CVD apparatus)
2a carrier gas source
2b carrier gas (diluent) source
3a flow rate regulating valve
3b flow rate regulating valve
4 mist generating source
4a raw material solution
4b mist
5 container
5a water
6 ultrasonic vibrator
7 deposition chamber
8 hot plate
9 supply pipe
10 substrate
101a n⁻-type semiconductor layer
101b n⁺-type semiconducting layer
102 ohmic electrode
103a metal layer
103b metal layer
103c metal layer
104 dielectric film
104a opening
105a Schottky electrode
105b ohmic electrode

1. A semiconductor device comprising:
a semiconductor layer;
a dielectric film provided on the semiconductor layer and having an opening and provided over a distance of at least 0.25 μm from the opening; and
an electrode layer provided over a part or all of the dielectric film from the inside of the opening,
wherein the dielectric film has a thickness of less than 50 nm from the opening to a distance of 0.25 μm, and has relative permittivity of 5 or less.

2. The semiconductor device according to claim 1, wherein the dielectric film is provided over a distance of at least 0.5 μm from the opening, and the thickness of the dielectric film is less than 50 nm from the opening to a distance of 0.5 μm.

3. The semiconductor device according to claim 1, wherein the dielectric film is provided over a distance of at least 1 μm from the opening, and the thickness of the dielectric film is less than 50 nm from the opening to a distance of 1 μm.

4. The semiconductor device according to claim 1, wherein the semiconductor layer contains an oxide semiconductor as a main component.

5. The semiconductor device according to claim 4, wherein the oxide semiconductor contains at least one or more metals selected from aluminum, indium and gallium.

6. The semiconductor device according to claim 4, wherein the oxide semiconductor contains at least gallium.

7. The semiconductor device according to claim 4, wherein the oxide semiconductor has corundum structure.

8. The semiconductor device according to claim 1, wherein the electrode layer contains at least one metal selected from Groups 4 to 10 of the Periodic Table.

9. The semiconductor device according to claim 1, wherein the electrode layer contains at least one metal selected from Groups 4 and 9 of the Periodic Table.

10. The semiconductor device according to claim 1, wherein the electrode layer includes two or more layers having different compositions.

11. The semiconductor device according to claim 1, wherein a thickness of the dielectric film at a position of an outer edge portion of the electrode layer is thicker than a thickness of the dielectric film from the opening to a distance of 1 μm.

12. The semiconductor device according to claim 1, wherein the density of fixed charges in the semiconducting layers is 1×10¹⁷/cm³ or less.

13. The semiconductor device according to claim 1, wherein the semiconductor device includes a Schottky barrier diode.

14. The semiconductor device according to claim 1, wherein the semiconductor device includes a power device.

15. A semiconductor system employing the semiconductor device according to claim 1.
